(19) United States
(12) Patent Application Publication
(10) Pub. No.: US 2007/0252649 A1
(43) Pub. Date: Nov. 1, 2007

(54) AMPLIFIER

(76) Inventor: Kazumi SHIIKUMA, Tokyo (JP)

Correspondence Address: OSTROLENK FABER GERB & SOFFEN, 1180 AVENUE OF THE AMERICAS, NEW YORK, NY, 100368403, US

(21) Appl. No.: 11/740,382

(22) Filed: Apr. 26, 2007

(30) Foreign Application Priority Data
Apr. 26, 2006 (JP) 121529/2006

(51) Int. Cl. H03F 3/68

(52) U.S. Cl. 330/295

(57) ABSTRACT

In a constant amplitude wave-combining type amplifier for splitting a single input signal into two parts by a distributor 1, amplifying the split signal parts by first and second amplifiers 3a, 3b and then combining output signals amplified thereby, the amplifiers 3a, 3b comprise at least two amplifier elements accommodated in a single package. Also, the amplifier elements constituting the first and second amplifiers 3a, 3b are packaged in a close relationship to each other. Moreover, the amplifier elements constituting the first and second amplifiers 3a, 3b may be either field effect transistors or bipolar transistors.

### BACKGROUND OF THE INVENTION

This application claims benefits of Japanese Patent Application No. 2006-121529 filed on Apr. 26, 2006, the contents of which are incorporated by the references.

The present invention relates generally to an amplifier, more specifically to a power amplifier to be used for wireless communication system or the like.

Requirements for a power amplifier to be used for wireless communication system include linearity, high efficiency and compactness. Particularly, in more recent multiple digital modulation communication system or the like, there often encounters cases to handle signals that vary over a wide range in average value of signal amplitude and also in the maximum amplitude. In case of amplifying such signals in a conventional power amplifier, the operation point of such amplifier is set so that signals up to the maximum amplitude can be amplified without causing signal distortion. This means that the amplifier rarely operates at or near the saturation output in which a relatively high efficiency is maintained, thereby generally resulting in poor efficiency.

In order to solve such problems, various technologies have been developed to improve efficiency of such amplifier while maintaining linearity. Examples of the technologies include a Doherty amplifier and a constant amplitude wave-combining amplifier that is commonly known as a LINC (Linear Amplification with Non-Linear Components) amplifier or an outphasing amplifier (referred to as a LINC amplifier below for simplicity). The basic construction of the LINC amplifier is well known to a person having an ordinary skill in the art based on publication such as the non-patent publication (“Efficiency of Outphasing RF Power Amplifier Systems” by Frederik H. Raab, in 1985 IEEE Trans. on Comm., Vol. COM-33, No. 10, pp 1094-1099) or the like. Accordingly, no description will be given herein on the principle of operation.

The construction of one example of the conventional LINC amplifier is shown in FIG. 3. In FIG. 3, an input signal is separated into constant amplitude signals in system 1 and system 2 by a distributor 1 disposed at the input side of the LINC amplifier. Thereafter, the signal is respectively amplified by a first amplifier 3a and a second amplifier 3b in the two systems before being combined by a combiner 2 for providing a desired output signal from the LINC amplifier. Conventionally, amplifiers 3a, 3b in the two systems that are key components of in the LINC amplifier are constructed with amplifying devices separately packaged in packages 10a, 10b, respectively.

One example of such amplifier is shown in FIG. 2 in the publication of “Investigation of a Highly Efficient LINC Amplifier Topology” in 2001 IEEE Vehicular Technology Conference Fall 2001, October 2001, pp 1215-1219 written jointly by Bo Shi and Lars Sunderson. In such conventional construction, each amplifier 3a, 3b uses a transistor separately accommodated in a separate package 10a, 10b, thereby occupying a larger mounting area for such transistors in 2 packages. This is disadvantageous for reducing size of the entire equipment. It is also disadvantageous in cost because of using two separate amplifiers.

### SUMMARY OF THE INVENTION

It is therefore an object of the present invention to provide a constant amplitude wave-combining amplifier that is compact in size and less expensive to make.

In order to achieve the above object, the according to an aspect of the present invention, there is provided a constant amplitude wave-combining amplifier, comprising at least a distributor for splitting a single input signal into two parts, a first amplifier for amplifying one part of the signals from the distributor, a second amplifier for amplifying another part of the signals from the distributor, and a combiner for combining the output signals from the first and second amplifiers in the two systems, characterized in that: the first and second amplifiers comprise at least two amplifier elements accommodated in a single package.

The amplifying elements constituting the first and second amplifiers are mounted in a close relationship to each other. The amplifying elements constituting the first and second amplifiers are field effect transistors. The amplifying elements constituting the first and second amplifiers are bipolar transistors.

According to another aspect of the present invention, there is provided a power amplifier to provide an intended large power output by amplifying in parallel a common input signal using first and second amplifiers whose output signals are combined together, characterized in that: the first and second amplifiers employ at least two substantially equal transistors accommodated in a single package designed for push-pull amplifier applications.

The transistors are packaged in a substantially rectangular package in a side-by-side relationship.

In the amplifier according to the present invention, since first and second amplifiers constituting two systems of constant amplitude wave-combining type amplifier comprises at least two amplifier devices accommodated in a single package, it helps to make any equipment employing such amplifier compact and low cost.

### BRIEF DESCRIPTION OF THE DRAWINGS

In the accompanying drawings, FIG. 1 is a block diagram of one embodiment of the amplifier according to the present invention;

FIG. 2 is an external appearance of a field effect transistor MRF5P 21180;

FIG. 3 is a block diagram of one example of a conventional LINC amplifier; and

FIG. 4 is an external appearance of a field effect transistor MRF21090.

### DESCRIPTION OF PREFERRED EMBODIMENT OF THE INVENTION

Now, preferred embodiments of the amplifier according to the present invention will be described in detail with reference to the accompanying drawings.

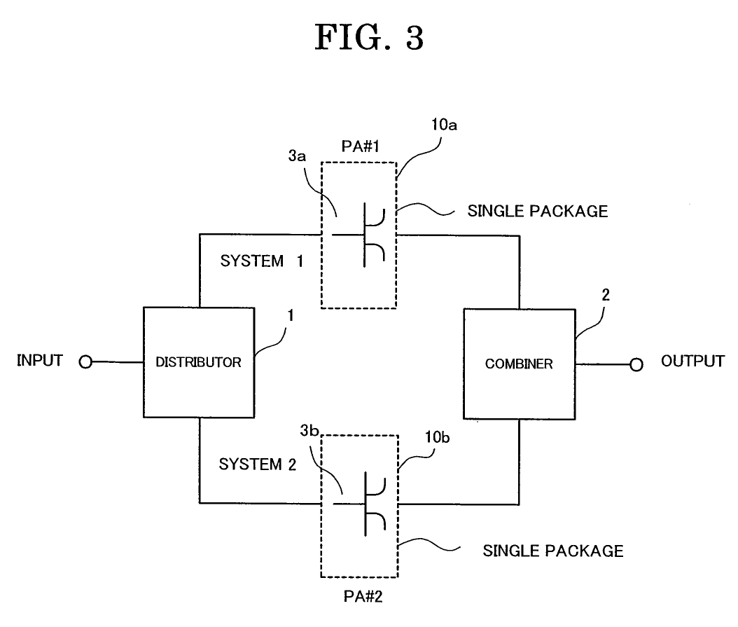

FIG. 1 shows the construction of an embodiment of the amplifier according to the present invention. As shown in FIG. 1, the LINC amplifier of the embodiment according to the present invention comprises, similar to the conventional amplifier, a distributor 1 for splitting the input signal into two parts, an amplifier 3a that receives one part of the signal from the distributor 1, an amplifier 3b that receives another part of the signal from the distributor 1 and a combiner 2 for combining output signals from the amplifiers 3a and 3b. It is to be noted, however, that the LINC amplifier in FIG. 1 differs from the conventional amplifier as shown in FIG. 3 in that the first and second amplifiers 3a and 3b are accommodated in a single package 10, thereby constituting a single device including at least 2 amplifier elements. As a result, it is compact and low cost as compared to the conventional amplifier.

Although the amplifier elements in the LINC amplifier are shown in FIG. 1 as field effect transistors, the present invention should not be restricted only to field effect transistors but may be bipolar transistors or any other elements having similar functions. Also, it is to be noted that distributor 1 and the combiner 2 in the embodiment in FIG. 1 may be replaced by any other known alternative circuits. However, since such alternative circuits are well known to a person having an ordinary skill in the art and they are not directly related to the present invention, no detailed description will be made herein.

Now, the construction of the embodiment of the LINC amplifier as shown in FIG. 1 will be described in detail by way of an example.

Consideration is made on an example of a typical LINC amplifier having 180 watts in saturation output at 2 GHz frequency band. In a conventional design, it is typical to use elements having an equal output as the amplifiers 3a and 3b in the two systems. In other words, each amplifier 3a, 3b have a 90 watts output, thereby providing a 180 watts in total as the LINC amplifier.

In this case, a preferable choice of the transistors to provide a 90 watts output is a field effect transistor model “MRF21090” available from Freescale Semiconductor Inc., in which each device is accommodated in a single package. The inventor believes that the “MRF21090” is one of the most compact products among transistors having the intended output.

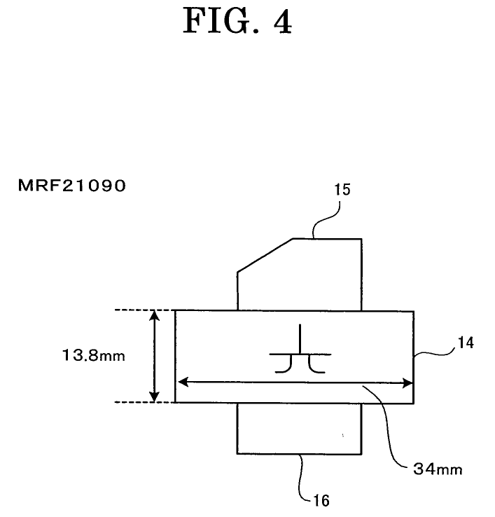

FIG. 4 shows an outer appearance of the “MRF21090” field effect transistor. As shown in FIG. 4, the “MRF21090” field effect transistor is constructed in a package (or flange) 14 and has a single gate electrode 15 and a single drain electrode 16. The external dimension of the “MRF21090” field effect transistor excluding the electrode portions is about 34 mm×13.8 mm (or about 1.34 inches×0.54 inch) per device. This means that at least as wide area as about 9.4 cm² (or about 1.46 square inches) is required for mounting 2 such transistors constituting the LINC amplifier.

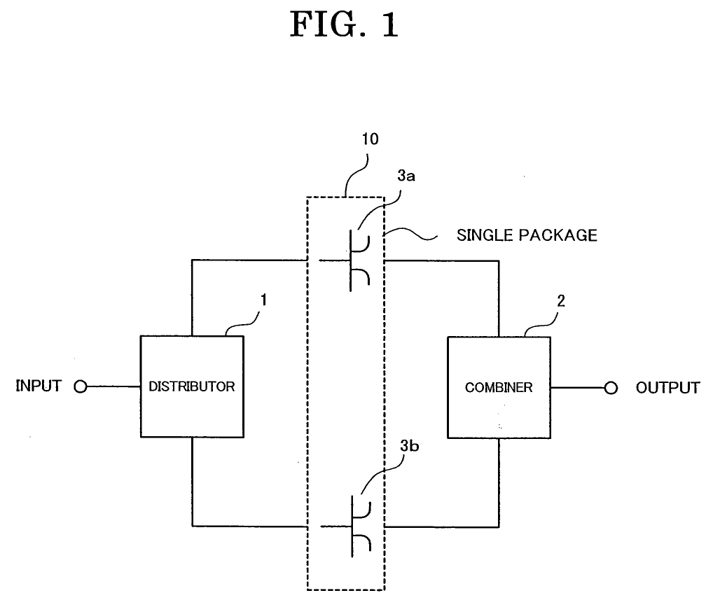

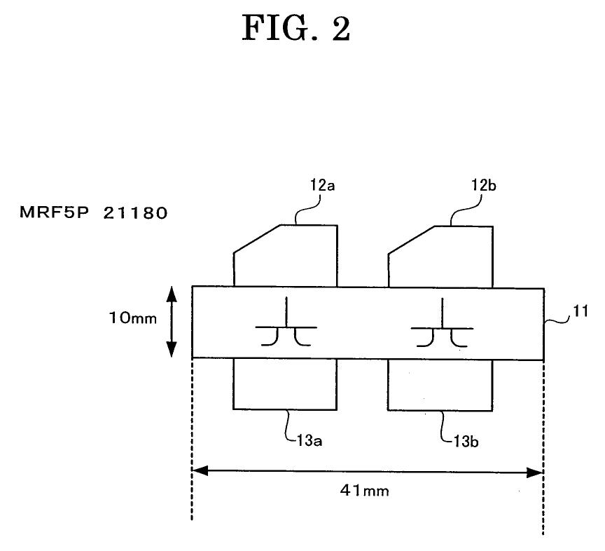

On the other hand, in the present invention, a 180 watts LINC amplifier is designed by using field effect transistors in a single package according to the present invention. One possible candidate of the transistors is a “MRF5P 21180” containing 2 transistors in a single package to provide a 180 watts output as a push-pull application also available from Freescale Semiconductor Inc. FIG. 2 shows an outer appearance of the “MRF 5P 21180” field effect transistors. As shown in FIG. 2, the “MRF 5P 21180” field effect transistors is designed in a single package (or flange) 11 to have a pair of gate electrodes 12a, 12b and a pair of drain electrodes 13a, 13b.

In this case, the outer dimension of the “MRF 5P 21180” field effect transistor as shown in FIG. 2 is about 41 mm×10 mm (or about 1.61 inches×0.39 inch) excluding electrode portions, thereby requiring a mounting area of about 4.1 cm² (or about 0.64 square inch) for the transistor portion of the LINC amplifier. This means that the mounting area for the transistor portion of the LINC amplifier in FIG. 2 is only about 43% in comparison with the case in FIG. 4, thereby enabling to construct the LINC amplifier with significantly reduced size. Even if peripheral circuits and the like are taken into consideration, the LINC amplifier according to the present invention can be more compact and lower cost as compared with the conventional construction.

As understood from the above description, the mounting area for the circuit portion constituting the LINC amplifier can be reduced, thereby enabling to make equipment using such LINC amplifier compact and low cost.

Additionally, in the present invention, amplifier elements for the amplifiers 3a and 3b accommodated in a single package can be located closed to each other, thereby thermally coupling them so as to stably operate in a common temperature condition.

It was conventional to provide a device including a couple of amplifier elements such as transistors or the like for push-pull amplifier or balanced amplifier applications. However, in the present invention, one of a plurality of amplifier elements accommodated in a single package is used as an amplifier for one system, while the other is used as an amplifier for the other system, thereby enabling to construct the compact and low cost LINC amplifier as a total using a single package construction.

A preferred embodiment of the present invention has been described hereinabove. It is to be noted, however, that the embodiment is simply to demonstrate an example of the present invention rather than restricting it. Various modifications and alternations can be made on the present invention by a person having an ordinary skill in the art without departing from the scope and spirit of the present invention.

What is claimed is:

1. A constant amplitude wave-combining amplifier, comprising at least a distributor for splitting a single input signal into two parts, a first amplifier for amplifying one part of the signals from the distributor, a second amplifier for amplifying another part of the signals from the distributor, and a combiner for combining the output signals from the first and second amplifiers in the two systems, characterized in that:
the first and second amplifiers comprise at least two amplifier elements accommodated in a single package.

2. An amplifier of claim 1, wherein the amplifying elements constituting the first and second amplifiers are mounted in a close relationship to each other.

3. An amplifier in claim 1, wherein the amplifying elements constituting the first and second amplifiers are field effect transistors.

4. An amplifier of claim 1, wherein the amplifying elements constituting the first and second amplifiers are bipolar transistors.

5. A power amplifier to provide an intended large power output by amplifying in parallel a common input signal using first and second amplifiers whose output signals are combined together, characterized in that:
the first and second amplifiers employ at least two substantially equal transistors accommodated in a single package designed for push-pull amplifier applications.

6. A power amplifier of claim 5, wherein the transistors are packaged in a substantially rectangular package in a side-by-side relationship.
